(19) United States
(12) Patent Application Publication
(10) Pub. No.: US 2009/0236629 A1
(43) Pub. Date: Sep. 24, 2009

(54) Sustrate and Semiconductor Light-Emitting Device

(75) Inventors: Naohiro Nishikawa, Ibaraki (JP); Kazumasa Ueda, Ibaraki (JP); Kenji Kasahara, Ibaraki (JP); Yoshihiko Tsuchida, Ibaraki (JP)

Correspondence Address: FITCH, EVEN, TABIN & FLANNERY, P. O. BOX 18415, WASHINGTON, DC, 20036, US

(73) Assignee: SUMITOMO CHEMICAL COMPANY, LIMITED, Chuo-ku, Tokyo (JP)

(21) Appl. No.: 11/922,497

(22) PCT Filed: Jul. 5, 2006
(86) PCT No.: PCT/JP2006/313813

§ 371 Date: Dec. 19, 2007

(30) Foreign Application Priority Data
Jul. 8, 2005 (JP) 2005-200308

(51) Int. Cl. H01L 33/00; H01L 21/308; H01L 29/06

(52) U.S. Cl. 257/103; 438/46; 257/618; 438/735; 257/E33.023; 257/E21.231; 257/E29.022

(57) ABSTRACT

The present invention provides a substrate and a semiconductor light emitting device. Convexes having a curved surface are formed on the substrate. The semiconductor light emitting device comprises a substrate on which convexes having a curved surface are formed and a semiconductor layer on the substrate.

### TECHNICAL FIELD

The present invention relates to a substrate and a semiconductor light emitting device. More specifically, the present invention relates to a group 3-5 nitride semiconductor light emitting device having high brightness and to a substrate suitable for producing the device.

### BACKGROUND ART

A group 3-5 nitride semiconductor light emitting device has been used as a light source for liquid crystal display, a light source for large screen display, a light source for white-light luminaire, a light source for writing/reading signals on DVDs and the like. The semiconductor light emitting device includes, for example, a substrate, an n-type semiconductor layer, a light emitting layer and a p-type semiconductor layer in this order; the light emitting layer is made of a compound represented by formula InₓGa_{y}Al_{z}N (0≦x≦1, 0≦y≦1, 0≦z≦1, x+y+z=1), an n-type electrode is formed on the n-type semiconductor layer, and a p-type electrode is formed on the p-type semiconductor layer. It is proposed the semiconductor light emitting device is applied to a light source such as ultraviolet, blue or green light emitting diode and ultraviolet, blue or green light laser diode.

In recent years, a high-brightness semiconductor light emitting device is required from the viewpoint of improving the performance of display device and luminaire.

### DISCLOSURE OF THE INVENTION

An object of the present invention is to provide a substrate suitable for producing a high-brightness semiconductor light emitting device. Another object of the present invention is to provide a semiconductor light emitting device.

The present inventors have intensively studied to solve the above-described problem, and resultantly completed the present invention.

The present invention provides a substrate on which convexes having a curved surface are formed.

The present invention provides a method for producing a substrate comprising the steps of (1) and (2):

(1) placing inorganic particles on a substrate, and

(2) dry-etching the substrate and the inorganic particles to form convexes.

The present invention provides a semiconductor light emitting device comprising a substrate on which convexes having a curved surface are formed and a semiconductor layer on the substrate.

Furthermore, the present invention provides a method for producing a semiconductor light emitting device comprising the steps of (1) to (3):

(1) placing inorganic particles on a substrate,

(2) dry-etching the substrate and the inorganic particles to form convexes, and

(3) growing semiconductor layers on the substrate.

### BRIEF DESCRIPTION OF DRAWINGS

FIG. 1 shows steps (a) to (c) of producing a substrate.

FIG. 2 shows a embodiment of convexes on the substrate.

FIG. 3 shows another embodiment of convexes on the substrate.

FIG. 4 shows the layer structure of a semiconductor light emitting device.

FIG. 5 shows an electron microscope image of the substrate obtained in Example 3.

FIG. 6 shows an electron microscope image of the substrate obtained in Example 4.

### DESCRIPTION OF REFERENCE NUMERALS

1 substrate
1A, 1C substrate surface
1B convex
2 inorganic particle
3 n-type group 3-5 nitride semiconductor
4 light emitting layer
5 p-type group 3-5 nitride semiconductor
6 n-type electrode
7 p-type transparent electrode
8 p-type electrode
10 group 3-5 nitride semiconductor light emitting device

### MODE OF CARRYING OUT THE INVENTION

### Substrate

The substrate according to the present invention has convexes.

The substrate is made of, for example, sapphire, SiC, Si, MgAl₂O₄, LiTaO₃, ZrB₂ or CrB₂.

The convexes have at least one curved surface, and they are usually formed into an island shape on the substrate and made of the same material as the substrate. The convexes are, for example, in the shape of cone or truncated cone having a curved surface or in the shape of pyramid or truncated pyramid, or may be in the shape of hemisphere.

Furthermore, the convexes have a height of usually not less than about 10 nm, preferably not less than 30 nm, and usually not more than 5 μm, preferably not more than 3 μm. The substrate with the convexes having the above-mentioned height can allow group 3-5 nitride semiconductor layers to grow easily, and a high-brightness compound semiconductor light emitting device is obtained.

Moreover, the convexes has a taper angle of usually not less than 5°, preferably not less than 10°, and usually not more than 90°, preferably not more than 80°.

### [Method for Producing a Substrate]

The method for producing a substrate according to the present invention includes the above step (1).

The substrate used at step (1) is made of, for example, sapphire, SiC, Si, MgAl₂O₄, LiTaO₃, ZrB₂ or CrB₂.

The inorganic particles are made of, for example, oxide, nitride, carbide, boride, sulfide, selenide or metal. Examples of the oxide include silica, alumina, zirconia, titania, ceria, zinc oxide, tin oxide and yttrium aluminum garnet (YAG). Examples of the nitride include silicon nitride, aluminum nitride and boron nitride. Examples of the carbide include silicon carbide (SiC), boron carbide (BC), diamond, graphite and fullerenes. Examples of the boride include zirconium boride (ZrB₂) and chromium boride (CrB₂). Examples of the sulfide include zinc sulfide, calcium sulfide, cadmium sulfide and strontium sulfide. Examples of the selenide include zinc selenide and cadmium selenide. In the oxide, nitride, carbide, boride, sulfide and selenide, an element contained therein may be partially substituted with another element, and examples thereof include silicate phosphor and aluminate phosphor which contain cerium or europium as an activator. Examples of the metal include silicon (Si), nickel (Ni), tungsten (W), tantalum (Ta), chromium (Cr), titanium (Ti), magnesium (Mg), calcium (Ca), aluminum Al), gold (Au), silver (Ag) and zinc (Zn). Furthermore, the inorganic particles may be made of mixture or composite which is made of at least two of oxide, nitride, carbide, boride, sulfide, selenide and metal. The inorganic particles may also be made of, for example, SIALON containing silicon, aluminum, oxygen and nitrogen. The inorganic particles are made of preferably oxide, more preferably silica.

The inorganic particles may be in the shape of sphere, multi-sided pyramid, rectangular parallelepiped or needle, or may have an unspecified shape (amorphous). Among these shapes, shapes having no directivity are preferable; for example, the shape of sphere is preferable.

When the inorganic particles are in the shape of sphere, the inorganic particles have an average particle diameter of usually not less than 5 nm, preferably not less than 10 nm, and usually not more than 50 μm, preferably not more than 10 μm. The average particle diameter is a volume average particle diameter and measured using centrifugal sedimentation.

The inorganic particles preferably have a uniform shape (a uniform particle diameter in case of the shape of sphere).

Placement of the inorganic particles may be carried out using a method in which inorganic particles are dispersed in solvent (for example, water, methanol, ethanol, isopropanol, n-butanol, ethylene glycol, dimethyl acetamide, methyl ethyl ketone or methyl isobutyl ketone) to obtain a slurry, and a substrate is dipped into the slurry and then dried, or a method in which the slurry is applied or sprayed onto the substrate and the substrate is dried. Drying may be carried out with a spinner.

The coverage of the inorganic particles placed on the substrate is usually not less than 0.1%, preferably not less than 5%, and usually not more than 90%, preferably not more than 80%. When the coverage is within the above range, it is possible to produce a substrate suitable for producing a semiconductor light emitting device having higher brightness. The coverage may be measured by observing the surface of a substrate on which inorganic particles are placed using a scanning electron microscope (SEM) and by calculating the following equation using the number P of inorganic particles and an average particle diameter d in the measured view (area S).

Coverage (%)=[(d/2)²×π×P×100]/S

The method for producing a substrate further includes the above step (2).

Dry-etching may be carried out using a conventional apparatus such as an ICP dry etching apparatus or an ECR dry etching apparatus. Dry-etching may be carried out under conditions that convexes with given shape and height are formed. For example, dry-etching may be carried out under the following conditions:

Substrate bias power: 200 to 400 W

ICP power: 100 to 300 W

Pressure: 1.5 to 2.5 Pa

Chlorine gas: 20 to 40 sccm

Boron trichloride gas: 40 to 60 sccm

Argon gas: 150 to 250 sccm

Etching time: 1 to 60 minutes

The etching depth is usually equal to the average height of the convexes formed on the substrate, usually not less than about 10 nm, preferably not less than about 30 nm, and usually not more than about 5 μm, preferably not more than about 3 μm.

The shape and size of the convexes formed by dry-etching depend on the material, shape and size of the inorganic particles. In case that the inorganic particles are placed on the substrate and that the substrate is subjected to dry-etching, the inorganic particles work as etching mask. The surface area of the substrate which is the outside of shadows of the inorganic particles is etched preferentially. The inorganic particles are also etched simultaneously, and the shape and size of the inorganic particles are changed as the etching proceeds, whereby the material, shape and size of the inorganic particles have effects on the etching of the substrate.

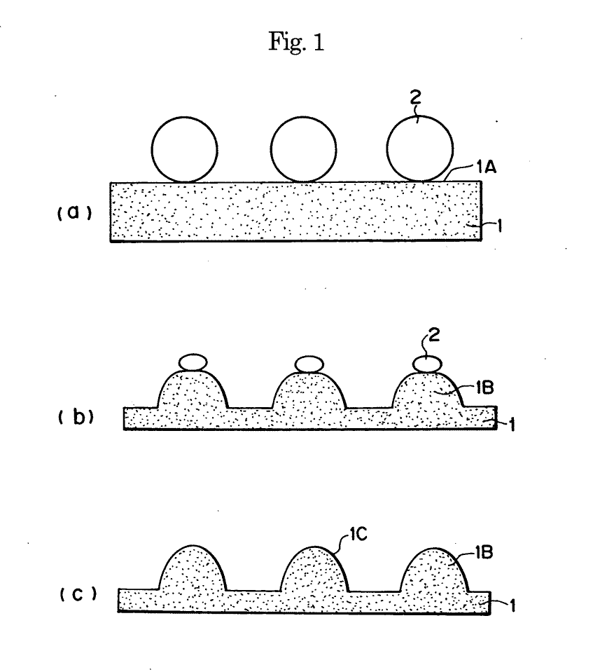

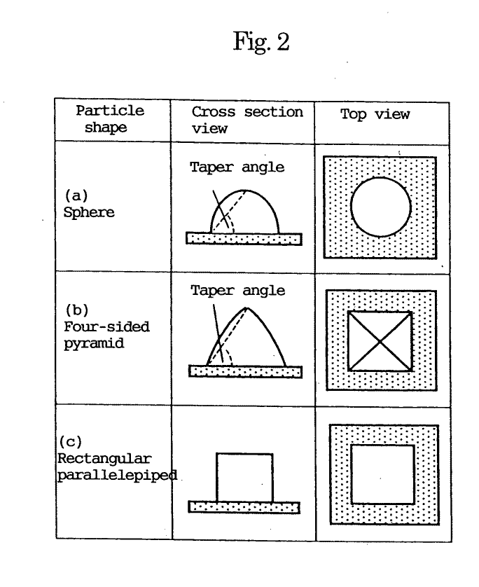

For example, when dry-etching is carried out under the conditions that the inorganic particles are in the shape of sphere, that the size (diameter) of the inorganic particles decreases gradually and that the inorganic particles vanish in the end, convexes having a nearly hemispherical shape or a nearly conic shape are formed. When dry-etching is carried out after inorganic particles 2 are placed on the surface 1A of a substrate 1 as shown in FIG. 1(a), the surface area of the substrate 1 which is the outside of shadows of the inorganic particles 2 is not etched, but the other area is etched, and convexes are formed, and the inorganic particles 2 are also dry-etched simultaneously; as a result, convexes 1B are formed as shown in FIG. 1(b). When dry-etching is further carried out continuously, the inorganic particles 2 vanish, and the convexes 1B remain as shown in FIG. 1(c). The obtained convexes usually have a predetermined taper angle as shown in FIG. 2(a).

When dry-etching is carried out under the conditions that the inorganic particles are in the shape of square pyramid, that the size of the inorganic particles decreases gradually and that the inorganic particles vanish in the end, convexes having a nearly square pyramid shape are formed as shown in FIG. 2(b). The obtained convexes usually have a predetermined taper angle.

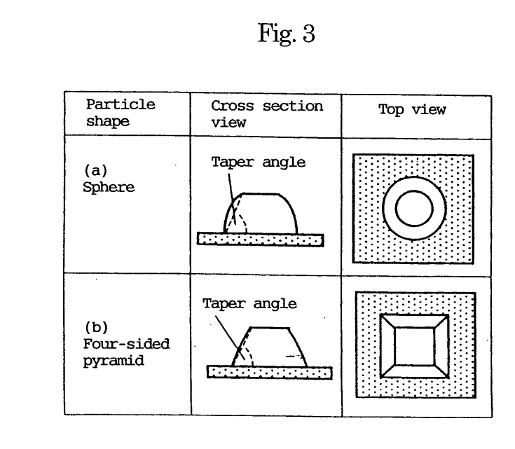

When dry-etching is carried out under the conditions that the inorganic particles are in the shape of sphere, that the size (diameter) of the inorganic particles decreases gradually but that the inorganic particles remain, convexes having a nearly truncated conical shape are formed as shown in FIG. 3(a). The obtained convexes usually have a predetermined taper angle.

When dry-etching is carried out under the conditions that the inorganic particles are in the shape of square pyramid, that the size of the inorganic particles decreases gradually but that the inorganic particles remain, convexes having a nearly truncated square pyramid shape are formed as shown in FIG. 3(b). The obtained convexes usually have a predetermined taper angle.

Furthermore, when dry-etching is carried out after inorganic particles are in the shape of rectangular parallelepiped are placed, convexes having a rectangular parallelepiped shape are formed as shown in FIG. 2(c).

The taper angle adjustment of the convexes may be carried out, for example, by changing the ratio (hereinafter referred to as a selective ratio) of the substrate dry-etching rate to the inorganic particle dry-etching rate. For example, when dry-etching is carried out at a high selective ratio, the maximum diameter (hereinafter referred to as particle size L) of the inorganic particles in a direction in parallel with the surface of the substrate decreases gradually; as a result, the taper angle of the convexes increases. On the other hand, when dry-etching is carried out at a low selective ratio, the particle size L of the inorganic particles decreases quickly; as a result, the taper angle of the convexes decreases.

The selective ratio usually depends on the material of the substrate, the dry-etching conditions and the material of the inorganic particles. The selective ratio may be adjusted by changing the conditions and so on.

The method for producing a substrate according to the present invention may further include step (4).

(4) removing the inorganic particles from the substrate.

Step (4) is a step of removing the inorganic particles remaining on the substrate after dry-etching at step (3). The removal may be carried out, for example, by a chemical method in which an etchant having an ability to etch the inorganic particles and having no ability to etch the substrate is used, or a physical method in which a brush roll cleaner is used.

### [Semiconductor Light Emitting Device]

The semiconductor light emitting device according to the present invention includes the above substrate and a semiconductor layer on the substrate.

The semiconductor layer is a layer for providing the function of a semiconductor light emitting device. Examples thereof include semiconductor functional layer, electron transport layer, hole transport layer. The semiconductor functional layer is usually made of group 3-5 nitride represented by formula InₓGa_{y}Al_{z}N (0≦x≦1, 0≦y≦1, 0≦z≦1, x+y+z=1). It is preferable that at least one of the semiconductor functional layers has a refractive index different from the substrate, and it is further preferable that semiconductor functional layer contact with the substrate has a refractive index different from the substrate. For example, the semiconductor functional layers may include a buffer layer (e.g. GaN, AlN), clad layer with n-type conductivity (e.g. n-GaN, n-AlGaN), light emitting layer (e.g. InGaN, GaN), clad layer with p-type conductivity (e.g. undoped GaN, p-AlGaN) and cap layer (e.g. Mg-doped AlGaN, Mg-doped GaN) in this order, as described in JP-A-6-260682, JP-A-7-15041, JP-A-9-64419 and JP-A-9-36430.

The semiconductor light emitting device usually further includes an n-type electrode and a p-type electrode. These electrodes supply electric current to the light emitting layer and is made of metal such as Ni, Au, Pt, Pd, Rh, Ti or Al.

### [Method for Producing a Semiconductor Light Emitting Device]

The method for producing a semiconductor light emitting device according to the present invention includes the above steps (1) to (3). The steps (1) and (2) are the same as the steps of the method for producing a substrate.

The growth of the semiconductor layer at step (3) may be carried out by an epitaxy such as MOVPE, MBE or HVPE. In the growth of the semiconductor layer (e.g. group 3-5 nitride semiconductor functional layer) by MOVPE, the following material, carrier gas and optionally dopant material may be used. Examples of a group 3 material include trialkyl gallium represented by formula R₁R₂R₃Ga (R₁, R₂ and R₃ are lower alkyl groups), such as trimethyl gallium [(CH₃)₃Ga, hereafter referred to as TMG] or triethyl gallium [(C₂H₅)₃Ga, hereafter referred to as TEG]; trialkyl aluminum represented by formula R₁R₂R₃Al (R₁, R₂ and R₃ are lower alkyl groups), such as trimethyl aluminum [(CH₃)₃Al, hereafter referred to as TMA], triethyl aluminum [(C₂H₅)₃Al, hereafter referred to as TEA] or triisobutyl aluminum [(i-C₄H₉)₃Al]; trimethylamine alane [(CH₃)₃N:AlH₃]; trialkyl indium represented by formula R₁R₂R₃In (R₁, R₂ and R₃ are lower alkyl groups), such as trimethyl indium [(CH₃)₃In, hereafter referred to as TMI] or triethyl indium [(C₂H₅)₃In]; a material obtained by substituting one or two alkyl groups of trialkyl indium with a halogen atom, such as diethyl indium chloride [(C₂H₅)₂InCl]; and indium halide represented by formula InX₂ (X is a halogen atom), such as indium chloride [InCl₃]. These may be used singly or in combination.

Examples of a group 5 material include ammonia, hydrazine, methylhydrazine, 1,1-dimethylhydrazine, 1,2-dimethylhydrazine, t-butylamine and ethylenediamine. These should only be used singly or in combination. Among these materials, ammonia and hydrazine are preferable from the viewpoint that no carbon atom is contained in the molecule and that the semiconductor layer formed is prevented from carbon contamination.

Examples of the n-type dopant material include silane, disilane, germane and tetramethyl germanium.

Examples of the p-type dopant material include biscyclopentadiethyl magnesium [(C₅H₅)₂Mg], bismethylcyclopentadiethyl magnesium [(C₅H₄CH₃)₂Mg] and bisethylcyclopentadiethyl magnesium [(C₅H₄C₂H₅)₂Mg].

Furthermore, examples of the ambient gas during growing and the carrier gas of organometallic material include nitrogen, hydrogen, argon and helium, preferably hydrogen and helium.

These may be used singly or in combination.

The growth of the semiconductor layer may be carried out under conventional conditions. For example, the light emitting layer may be grown usually at not less than 600° C. and not more than 800° C., the layer with p-type conductivity may be grown usually at not less than 800° C. and not more than 1200° C., and the layer with n-type conductivity may be grown usually at not less than 800° C. and not more than 1200° C.

The growth of a semiconductor layer is exemplified below.

The substrate 1 on which the convexes 1B are formed, as shown in FIG. 1(c), is set on a susceptor in a reactor. The susceptor usually has a structure with a rotator for rotating the substrate 1 to allow a semiconductor layer to grow uniformly on the surface 1C of the substrate 1. The susceptor is heated using a heater such as an infrared lamp. A material gas is fed from a gas holder to the reactor through a supply line. The material gas fed to the reactor is thermally decomposed on the surface 1C of the substrate 1, and a semiconductor layer is grown on the surface 1C of the substrate 1. The unreacted material gas of the material gas fed to the reactor is exhausted from the reactor to the outside through an exhaust line and fed to an exhaust gas treatment equipment.

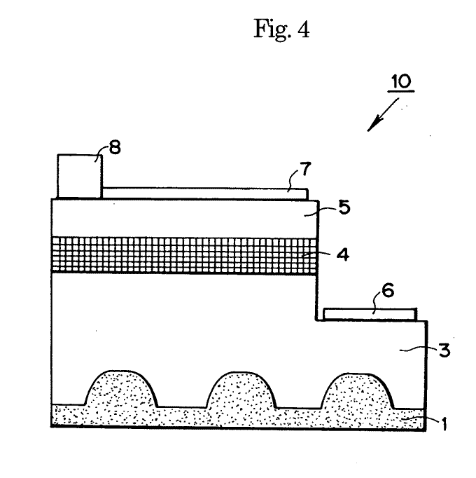

A group 3-5 nitride semiconductor functional layer is grown on the surface 1C of the substrate 1 by continuing the operation while changing material gas and heating temperature. The group 3-5 nitride semiconductor functional layer include a layer which is necessary for the group 3-5 nitride semiconductor light emitting device, and usually includes a layer with n-type conductivity (n-type group 3-5 nitride semiconductor layer 3 in FIG. 4), layer with p-type conductivity (p-type group 3-5 nitride semiconductor layer 5 in FIG. 4) and light emitting layer between these layers. The light emitting layer is preferably made of a group 3-5 nitride semiconductor represented by formula InₓGa_{y}Al_{z}N (0≦x≦1, 0≦y≦1, 0≦z≦1, x+y+z=1).

The method for producing a light emitting device usually includes a step of forming electrodes. In addition, the method for producing a light emitting device may include a step of forming other layer from the viewpoint of improving the crystallity of the layer with n-type conductivity, the light emitting layer or the layer with p-type conductivity. Examples of the other layer include an n-type contact layer, n-type clad layer, p-type contact layer, p-type clad layer, cap layer and buffer layer, or may include a thick-film layer and a super lattice thin-film layer.

According to the method for producing a semiconductor light emitting device, for example, the group 3-5 nitride semiconductor light emitting device 10 as shown in FIG. 4 is obtained. The group 3-5 nitride semiconductor light emitting device 10 includes the substrate 1, n-type group 3-5 nitride semiconductor layer 3, light emitting layer 4 and p-type group 3-5 nitride semiconductor layer 5 in this order. Furthermore, an n-type electrode 6 is formed on the n-type group 3-5 nitride semiconductor layer 3, and a p-type transparent electrode 7 and a p-type electrode 8 are formed on the p-type group 3-5 nitride semiconductor layer 5.

In the semiconductor light emitting device 10, when part of the light from the light emitting layer 4 reaches the substrate 1, the refraction and reflection of the light are disturbed, and total reflection is suppressed because the convexes with curved surface are formed on the substrate 1. As a result, the intensity of the light emitted from the p-type transparent electrode 7 of the semiconductor light emitting device 10 to the outside is increased.

### EXAMPLES

The present invention is described in more detail by following Examples, which should not be construed as a limitation upon the scope of the present invention.

### Example 1

### Preparation of a Substrate Having Convexes

A mirror polished c-face sapphire substrate was loaded onto a spinner. Slurry obtained by dispersing 4% by weight of spherical silica (HIPRESICA, manufactured by UBE-NITTO KASEI CO., LTD., average particle diameter: 5 μm) in ethanol was applied to the substrate while the spinner was stopped. After the spinner was rotated at 500 rpm for 10 seconds and at 2500 rpm for 40 seconds, the substrate was dried. The coverage of the silica on the substrate was 69%. The substrate was dry-etched using an ICP dry etching equipment under the following conditions, silica particles remaining at the tops of the convexes were removed using a cotton swab, and a substrate with convexes having a nearly hemispherical shape was obtained.

Dry Etching Conditions

Substrate bias power: 300 W

ICP power: 200 W

Pressure: 2.0 Pa

Chlorine gas: 32 sccm

Boron trichloride gas: 48 sccm

Argon gas: 190 sccm

etching time: 10 minutes

The substrate was etched by dry-etching about 2.25 μm in the vertical direction. The lateral size of the silica was decreased to an average size of 1.22 μm. The lateral size of the silica measured after the dry-etching was about 24.5% of its diameter measured before the dry-etching. The convexes had a side face with a taper angle of 50°.

### [Production of a Semiconductor Light Emitting Device]

Group 3-5 nitride semiconductor layers were epitaxially grown on the obtained substrate by MOVPE as described below.

The substrate was heated for 15 minutes at a susceptor temperature of 1040° C. and a pressure of 1 atm under hydrogen atmosphere, and the temperature of the susceptor was cooled to 485° C., a carrier gas (hydrogen), ammonia and TMG were fed to grow a GaN buffer layer having a thickness of about 500 Å. The temperature of the susceptor was elevated to 900° C., the carrier gas (hydrogen), ammonia and TMG were fed to grow an undoped GaN layer. The temperature of the susceptor was elevated to 1040° C., the pressure of the reactor was lowered to ¼ atm, the carrier gas (hydrogen), ammonia and TMG were fed to grow an undoped GaN layer having a thickness of about 5 μm. The carrier gas (hydrogen), ammonia, TMG and SiH₄ (as a Si source for growing n-type GaN layer) were fed to grow a Si-doped GaN layer having a thickness of about 5 μm. As a result, a group 3-5 nitride semiconductor epitaxial substrate was obtained.

Then, an n-type semiconductor layer, an InGaN light emitting layer (multi-quantum well structure, hereinafter referred to as MQW structure) and a p-type semiconductor layer were grown in this order on the group 3-5 nitride semiconductor epitaxial substrate to obtain an epitaxial substrate for a blue LED with an emission wavelength of 440 nm. The epitaxial substrate was subjected to etching step for exposing an n-type contact layer, electrode forming step and device isolation step to obtain a semiconductor light emitting device having the structure as shown in FIG. 4. The semiconductor light emitting device had a light output of 6.2 mW at a drive current of 20 mA.

### Example 2

The same operations as [Preparation of a substrate having convexes] of Example 1 were carried out, except that spherical silica (HIPRESICA, manufactured by UBE-NITTO KASEI CO., LTD., average particle diameter: 3 μm) was used and that the dry-etching time was changed to 3 minutes to obtain a substrate having convexes with a nearly hemispherical shape.

In this example, the coverage of the silica on the substrate before etching was 22%. The substrate was dry-etched at a depth of about 0.44 μm in the vertical direction. The lateral size of the silica was decreased to an average size of 2.38 μm. The lateral size of the silica after dry-etching was about 79.5% of its diameter-before dry-etching. The convexes had a side face with a taper angle of 55°.

The same operations as [Production of a semiconductor light emitting device] of Example 1 were carried out for the substrate to obtain a semiconductor light emitting device. The semiconductor light emitting device had a light output of 5.6 mW at a drive current of 20 mA.

### Example 3

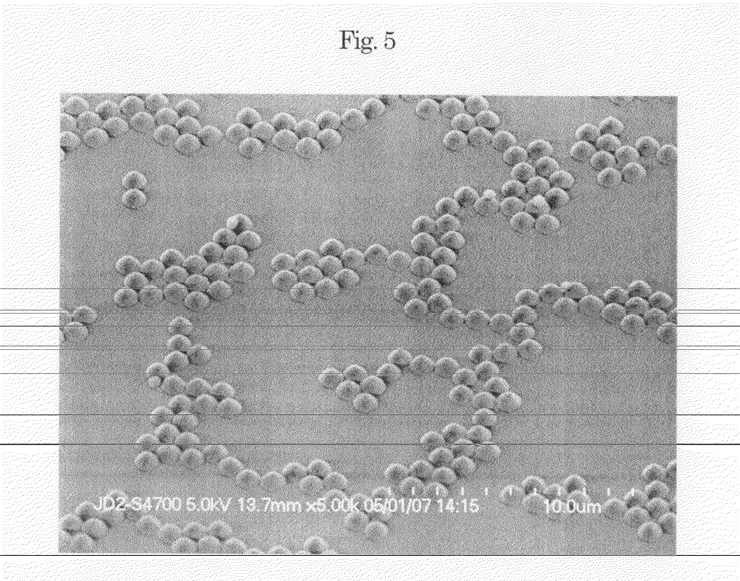

The same operations as [Preparation of a substrate having convexes] of Example 1 were carried out, except that spherical silica (HIPRESICA, manufactured by UBE-NITTO KASEI CO., LTD., average particle diameter: 1 μm) was used and that the dry-etching time was changed to 5 minutes to obtain a substrate having convexes with a nearly hemispherical shape. An electron microscope image of the substrate was shown in FIG. 5.

In this example, the coverage of the silica on the substrate before etching was 38%. The substrate was dry-etched at a depth of about 0.51 μm in the vertical direction. The lateral size of the silica was decreased to an average size of 0.20 μm. The lateral size of the silica after the dry-etching was about 20.3% of its diameter before the dry-etching. The convexes had a side face with a taper angle of 52°.

The same operations as [Production of a semiconductor light emitting device] of Example 1 were carried out for the substrate to obtain a semiconductor light emitting device. The semiconductor light emitting device had a light output of 5.5 mW at a drive current of 20 mA.

### Example 4

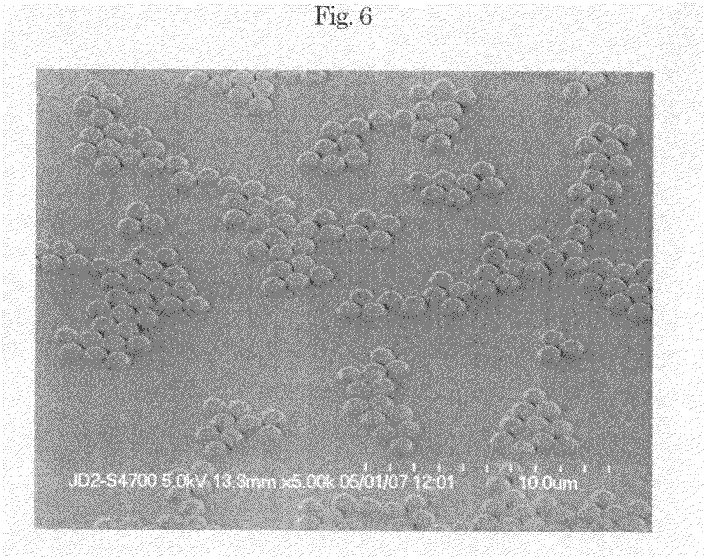

The same operations as Example 3 were carried out, except that the dry-etching time was changed to 3 minutes to obtain a substrate having convexes with a nearly hemispherical shape. An electron microscope image of the substrate was shown in FIG. 6.

In this example, the coverage of the silica on the substrate before etching was 38%. The substrate was dry-etched at a depth of about 0.25 μm in the vertical direction. The lateral size of the silica was decreased to an average size of 0.43 μm. The lateral size of the silica after the dry-etching was about 43.5% of its diameter before the dry-etching. The convexes had a side face with a taper angle of 53°.

The same operations as [Production of a semiconductor light emitting device] of Example 1 were carried out for the substrate to obtain a semiconductor light emitting device. The semiconductor light emitting device had a light output of 5.2 mW at a drive current of 20 mA.

### Comparative Example 1

The same operations as [Production of a semiconductor light emitting device] of Example 1 were carried out without performing the steps described in [Preparation of a substrate having convexes] of Example 1 to obtain a semiconductor light emitting device. The semiconductor light emitting device had a light output of 3.2 mW at a drive current of 20 mA.

### Comparative Example 2

A resist pattern having equilateral hexagons with a side length of 5 μm was formed by photolithography on a mirror polished c-face sapphire substrate, and Ni layer with a thickness of 5000 Å was deposited. The part outside the hexagons was lifted off to obtain Ni layer on the hexagons.

The obtained substrate was dry-etched using an ICP dry-etching equipment under the following conditions to remove Ni layer. A substrate having rectangular convexes was obtained. The convexes had a coverage of 54%.

Dry Etching Conditions

Substrate bias power: 300 W

ICP power: 200 W

Pressure: 2.0 Pa

Chlorine gas: 32 sccm

Boron trichloride gas: 48 sccm

Argon gas: 190 sccm

Etching time: 10 minutes

The same operations as [Production of a semiconductor light emitting device] of Example 1 were carried out for the substrate to obtain a semiconductor light emitting device. The semiconductor light emitting device had a light output of 4.0 mW at a drive current of 20 mA.

### INDUSTRIAL APPLICABILITY

The semiconductor light emitting device according to the present invention shows high brightness. In addition, a semiconductor light emitting device having high brightness is obtained using the substrate according to the present invention.

1. A substrate on which convexes having a curved surface are formed.

2. The substrate according to claim 1, wherein the convexes and the substrate are made of the same material.

3. The substrate according to claim 1, wherein the substrate is made of sapphire, sapphire, SiC, Si, MgAl₂O₄, LiTaO₃, ZrB₂ or CrB₂.

4. A method for producing a substrate comprising the steps of (1) and (2):
(1) placing inorganic particles on a substrate, and
(2) dry-etching the substrate and the inorganic particles to form convexes.

5. The method according to claim 4, wherein the substrate is made of sapphire, sapphire, SiC, Si, MgAl₂O₄, LiTaO₃, ZrB₂ or CrB₂.

6. The method according to claim 4, wherein the inorganic particles are made of at least one selected from the group consisting of oxide, nitride, carbide, boride, sulfide, selenide and metal.

7. The method according to claim 6, wherein the inorganic particles are made of oxide.

8. The method according to claim 7, wherein the oxide is made of silica.

9. The method according to claim 4, wherein the inorganic particles are in the shape of sphere, multi-sided pyramid, rectangular parallelepiped or needle.

10. A semiconductor light emitting device comprising a substrate on which convexes having a curved surface are formed and a semiconductor layer on the substrate.

11. The semiconductor light emitting device according to claim 10, wherein the substrate is made of sapphire, sapphire, SiC, Si, MgAl₂O₄, LiTaO₃, ZrB₂ or CrB₂.

12. The semiconductor light emitting device according to claim 10, wherein the semiconductor layer is made of group 3-5 nitride semiconductor compound.

13. A method for producing a semiconductor light emitting device comprising the steps of (1) to (3):
(1) placing inorganic particles on a substrate,
(2) dry-etching the substrate and the inorganic particles to form convexes, and
(3) growing a semiconductor layer on the substrate.

14. The method according to claim 13, comprising the step of (4) between step (2) and step (3):
(4) removing the inorganic particles from the substrate.

15. The method according to claim 13, wherein the substrate is made of sapphire, sapphire, SiC, Si, MgAl₂O₄, LiTaO₃, ZrB₂ or CrB₂.

16. The method according to claim 13, wherein the inorganic particles are made of at least one selected from the group consisting of oxide, nitride, carbide, boride, sulfide, selenide and metal.

17. The method according to claim 13, wherein the semiconductor layer is made of group 3-5 nitride semiconductor compound.
